(19) United States
(12) Patent Application Publication
(10) Pub. No.: US 2026/0324143 A1
(43) Pub. Date: Oct. 15, 2026

(54) DISPLAY DEVICE

(71) Applicant: LG Display Co., Ltd., Seoul (KR)

(72) Inventors: Hansaem KANG, Paju-si (KR); Jinhwa SHIN, Paju-si (KR); Bongseok CHOI, Paju-si (KR); Doyoung KWAK, Paju-si (KR); Jongmin JANG, Paju-si (KR); Youngsuk HWANG, Paju-si (KR)

(73) Assignee: LG Display Co., Ltd., Seoul (KR)

(21) Appl. No.: 19/636,803

(22) Filed: Apr. 1, 2026

(30) Foreign Application Priority Data
Apr. 14, 2025 (KR) 10-2025-0048136

(51) Int. Cl. H10H 20/832; H10H 20/831; H10H 20/857; H10H 29/39

(52) U.S. Cl. CPC H10H 20/835; H10H 20/8314; H10H 20/857; H10H 29/39

(57) ABSTRACT

A display device is disclosed. The display device includes a substrate, a transistor disposed on the substrate, a planarization layer disposed on the transistor, and a first reflective electrode disposed on the planarization layer. A first adhesive layer is disposed on the first reflective electrode, and a light emitting element is disposed on the first adhesive layer. A second reflective electrode is in contact with the light emitting element. The first reflective electrode and the second reflective electrode are in direct contact with each other. The second reflective electrode contacts an electrode of the light emitting element and surrounds at least a portion of a side surface of the light emitting element. The first reflective electrode reflects light emitted from the light emitting element, and the second reflective electrode provides an electrical connection to the light emitting element. The display device improves electrical connection stability and light extraction efficiency.

### CROSS REFERENCE TO RELATED APPLICATION

The present application claims benefit and priority to Korean Patent Application No. 10-2025-0048136, filed Apr. 14, 2025, the entire contents of which is incorporated herein for all purposes by reference.

### Technical Field

The present disclosure relates to a display device, and particularly to, for example, without limitation, a display device including a light-emitting element and a reflective electrode.

### BACKGROUND

With the development of an information-oriented society, various demands for display devices for displaying images have increased, and various types of display devices, such as liquid crystal display devices, and organic light emitting display devices have been used.

Among various display devices, the OLED device of an emissive type device may have advantages of a viewing angle and a contrast ratio as compared with the LCD device. Since an additional backlight unit is not required, the OLED device may have a light weight, a thin profile, and a low power consumption. In addition, the OLED device may be driven with a low voltage and has a fast response speed. Specifically, the OLED device has a low fabrication cost.

However, the OLED device which uses an organic matter may easily become a defective pixel because an organic light emitting layer and an electrode are oxidized due to permeation of moisture and oxygen or other foreign substance, and therefore, various technological configurations are additionally required so as to minimize or at least reduce permeation of moisture and oxygen.

The description provided in the background section should not be assumed to be prior art merely because it is mentioned in or associated with this section. The background section may include information that describes one or more aspects of the subject technology, and the description in this section does not limit the scope of the present disclosure.

### SUMMARY

Research and development with respect to a display device which uses an LED (light emitting diode) using an inorganic matter as a light emitting element has been recently underway, and such a light emitting diode display is in the spotlight as a next-generation display device because of high definition and high reliability. For example, inorganic LEDs may provide higher electro-optical conversion efficiency. Moreover, unlike OLEDs, they do not exhibit the typical use-induced efficiency degradation of organic emissive materials that may lead to a progressive increase in power consumption over time for a given luminance target. On the other hand, as LED display devices continue to scale toward smaller pixel sizes, there is an increasing need to more precisely control edge light leakage, as well as to improve the placement accuracy in transferring LED chips and the interconnection reliability of the chips.

Accordingly, the present disclosure is directed to a display device that substantially obviates one or more of the issues due to limitations and disadvantages of the related art. The inventors of the present disclosure have recognized problems of conventional display devices and have performed various experiments on a light-emitting element, which may improve electrical connection between an LED device, the stability of a contact process, and/or the light-extraction efficiency.

An aspect of the present disclosure is to provide a display device having smooth electrical connection between an LED device and a connection line.

Another aspect of the present disclosure is to provide a display device having improved stability of a contact process with an LED device.

Still another aspect of the present disclosure is to provide a display device having improved light-extraction efficiency.

The aspect of the embodiments of the present disclosure are not limited to the above-mentioned objects, and other technical aspect of may be inferred from the embodiments of the disclosure described in the detailed description below.

To achieve at least one of the above aspects and other aspects of the inventive concepts, as embodied and broadly described herein, a display device according to one aspect may include: a substrate; a transistor disposed on the substrate; a planarization layer disposed on the transistor; a first reflective electrode disposed on the planarization layer; a first adhesive layer disposed on the first reflective electrode; a light emitting element disposed on the first adhesive layer; and a second reflective electrode in contact with the light emitting element, and the first reflective electrode and the second reflective electrode may be in direct contact with each other.

A display device according to another embodiment may include: a substrate; a transistor disposed on the substrate; a planarization layer disposed on the transistor; a first reflective electrode disposed on the planarization layer; a first adhesive layer disposed on an upper surface of the first reflective electrode; a light emitting element disposed on the first adhesive layer; and a second reflective electrode disposed on the upper surface of the first reflective electrode, and the second reflective electrode may be disposed to surround at least a portion of the side surface of the light emitting element.

A display device according to still another embodiment, may include: a substrate; at least one transistor and a light emitting element disposed on the substrate; a planarization layer disposed on the transistor; a light emitting element accommodating member positioned on the planarization layer; and wherein the light emitting element accommodating member surrounds a bottom surface and at least a portion of a side surface of the light emitting element to accommodate the light emitting element, and the light emitting element accommodating member has reflective characteristics.

Other details of the embodiments are included in the detailed description and the accompanying drawings.

According to embodiments of the present disclosure, it is possible to provide a display device having smooth electrical connection to an LED device.

According to embodiments of the present disclosure, it is possible to provide a display device having improved stability of a process of a contact with an LED device.

According to embodiments of the present disclosure, it is possible to provide a display device having improved light-extraction efficiency.

According to embodiments of the present disclosure, because light-extraction efficiency is improved, low power of the display device can be implemented and thus, power consumption can be reduced.

The effects of the present disclosure are not limited to the above-described effects and other effects which are not described herein may be clearly understood by those skilled in the art from the following description of the embodiments of the present disclosure.

Additional features and aspects will be set forth in part in the description that follows, and in part will become apparent from the description, or may be learned by practice of the inventive concepts provided herein. It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principles of the disclosure. In the drawings:

FIG. 1 is a plan view of a display device according to an embodiment;

FIG. 2 is a view illustrating a cross-sectional structure of a sub-pixel according to an embodiment;

FIG. 3 is an enlarged view of Q1 region of FIG. 2;

FIG. 4 is a schematic view illustrating a path of light emitted from a light emitting layer;

FIGS. 5 to 8 are views illustrating steps of manufacturing a display device according to an embodiment;

FIG. 9 is a cross-sectional view of a display device according to another embodiment;

FIG. 10 is a cross-sectional view of a display device according to still another embodiment;

FIG. 11 is a cross-sectional view of a display device according to still another embodiment;

FIG. 12 is a cross-sectional view of a display device according to still another embodiment.

FIG. 13 is a cross-sectional view of a display device according to still another embodiment;

FIG. 14 is an enlarged view of Q2 region of FIG. 13; and

FIG. 15 is a cross-sectional view of a display device according to still another embodiment.

Throughout the drawings and the detailed description, unless otherwise described, the same drawing reference numerals should be understood to refer to the same elements, features, and structures.

### DETAILED DESCRIPTION

Hereinafter, the embodiments will be described with reference to the accompanying drawings. However, it should be understood that the present disclosure is not limited to the example embodiments described below, and various modifications may be made without departing from the spirit and scope of the present disclosure. And the terms used in the present disclosure are for the purpose of describing example embodiments only and are not intended to be limiting. In this specification, when a component (or, an area, a layer, a part, etc.) is referred to as being “on,” “connected to,” “coupled to,” “attached to,” “adhered to” or “combined to” another component, the component may be directly on, connected to, “coupled to,” “attached to,” “adhered to” or combined to the other component, or a third component therebetween may be present.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

Like reference numerals refer to like elements throughout.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure. The term “and/or” includes any and all combinations of one or more of the associated listed items.

It will be understood that when the terms “first” and “second” are used herein to describe various components, these components should not be limited by these terms. The above terms are used only to distinguish one component from another. For example, a first component may be referred to as a second component and vice versa without departing from the scope of the present disclosure. Singular expressions and terms used herein also encompass or include plural expressions and terms, unless the context clearly indicates otherwise.

In addition, terms such as “below,” “the lower side,” “on,” and “the upper side” are used to describe a relationship of configurations shown in the drawing. The terms are described as a relative concept based on a direction shown in the drawing. Consequently, the case in which a first element is positioned “on” a second element includes the case in which the first element is positioned “below” the second element as well as the case in which the first element is positioned “above” the second element in the figure or in an actual configuration.

In various embodiments of the present disclosure, the terms “include,” “comprise,” “including,” or “comprising,” may refer to a property, a fixed number, a step, a process, a component or combination thereof, but do not exclude other properties, fixed numbers, steps, processes, components, or combination thereof.

Shapes described in the present disclosure, such as circular, rectangular, polygonal, flat, curved, or stepped structures, are examples only, and other shapes achieving similar functionality may also be adopted.

Materials described herein are provided merely as examples and may be replaced by other materials having substantially the same physical or electrical characteristics.

The present disclosure describes a display device in which a light-emitting element (e.g., micro-LED) is mounted on a substrate and integrated with a dual reflective electrode structure that improves both electrical connection and optical efficiency. A first reflective electrode is positioned beneath the LED on a planarization layer, while a second reflective electrode is formed on exposed portions of the first reflective electrode and extends upward to contact the side of the LED electrode. Because the first and second reflective electrodes are in contact, they form a reflective enclosure around the LED, reflecting downward-emitted light upward and improving light-extraction efficiency while also providing a reliable electrical connection path between the LED and driving circuitry.

A segmented adhesive structure enables this configuration. A first adhesive layer under the LED secures the device to the reflective electrode, while a second adhesive layer is positioned outside the LED region and spaced apart from the first adhesive layer. The gap between these adhesive portions exposes the underlying reflective electrode, allowing the second reflective electrode to be deposited so that it contacts both the first reflective electrode and the LED electrode. This arrangement stabilizes LED placement, improves contact reliability, and allows the reflective electrodes to form a bowl-like cavity that contains and redirects emitted light.

The present disclosure also includes manufacturing and structural variations that further enhance performance. For example, the LED may act as a self-aligned mask during adhesive patterning, simplifying fabrication; the reflective electrode may include textured or thickness-varying regions to improve light scattering and extraction; and versions for flip-chip LEDs employ separated reflective electrode portions to maintain electrical polarity while preserving the reflective cavity structure. Collectively, these features integrate LED mounting, electrical interconnection, and optical reflection into a unified architecture that improves efficiency, process stability, and display reliability.

The details of the various embodiments of the present disclosure will be described in detail with reference to the accompanying drawings.

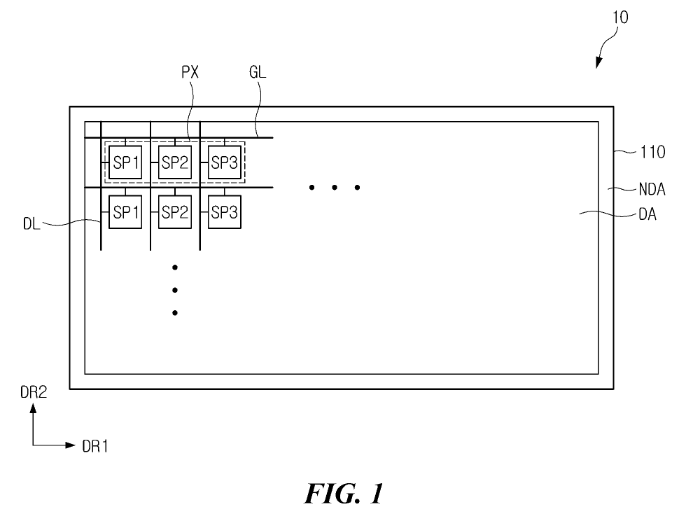

FIG. 1 is a plan view of a display device according to an embodiment.

Referring to FIG. 1, a display device 10 of this disclosure may be applied to a TV, a signage, a mobile terminal such as a handheld phone, a smart phone, etc., a display for a computer such as a laptop, a desktop, etc., a head-up display (HUD) for automobile, a backlight unit for a display, a display for AR, VR, and MR (mixed reality), etc., and a display for a vehicle or the like. However, the configuration according to the embodiments described in this disclosure may be equally applied to devices capable of displaying an image even if the devices are newly developed types which will be developed in the future.

The display device 10 may use a micro-LED as the light emitting element, but is not limited thereto.

The display device 10 may include a flexible display manufactured on a thin and flexible substrate. The flexible display may be bent or rolled like a paper while maintaining a characteristic of a conventional flat display.

The display device 10 may include a display region DA in which a plurality of pixels PX is disposed and a non-display region NDA. The display device 10 may include a substrate 110 providing a space in which the plurality of pixels PX can be disposed.

The display region DA is a region for displaying an image, a video, and the like, and a plurality of pixels PX may be disposed in the display region DA. The non-display region NDA is a region in which no screen is displayed, and may be referred to as a bezel region. The non-display region NDA may be disposed around the display region DA, but is not limited thereto. The non-display region NDA may be disposed to surround the display region DA, but is not limited thereto.

The non-display region NDA may be defined as a region on the substrate 110 excluding the display region DA, and may have a relatively narrower width (or size) compared to that of the display region DA, but is not limited thereto.

The pixel PX may consist of a plurality of sub-pixels such as SP1, SP2, and SP3, and each of the sub-pixels such as SP1, SP2, and SP3 may emit light in a different color such as red, blue, and green. However, the sub-pixels are not limited thereto, and may additionally or alternatively include a sub-pixel emitting light in white and the like. The sub-pixels SP1, SP2, and SP3 may be sequentially disposed along a first direction DR1.

The pixel PX may be repeatedly disposed along the first direction DR1 and a second direction DR2. In more detail, each of the sub-pixels SP1, SP2, and SP3 may be alternately and repeatedly disposed along the first direction DR1. Each of the sub-pixels SP1, SP2, and SP3 may be repeatedly disposed along the second direction DR2.

The display device 10 may further include a gate line GL and a data line DL electrically connected to the sub-pixels (e.g., SP1, SP2, and SP3) of each pixel PX. The gate line GL and the data line DL may provide a signal needed for the sub-pixels (e.g., SP1, SP2, and SP3) of each pixel PX.

The gate line GL may extend in the first direction DR1, and may be repeatedly disposed along the second direction DR2. The data line DL may extend in the second direction DR2, and may be repeatedly disposed along the first direction DR1. The gate line GL and the data line DL may intersect each other.

The substrate 110 may be an array substrate on which the transistors are formed, and may include a plastic material or a glass material.

The substrate 110 according to an embodiment may include an opaque or colored polyimide material. In this case, the substrate 110 may further include a back plate combined to a rear surface of the substrate 110 so as to maintain the substrate 110 in a flat state. The structure and material of the substrate is not limited thereto.

The back plate according to an embodiment may include a plastic material, for example, a polyethylene terephthalate material. The structure and material of the back plate are not limited thereto. For example, the back plate may also be formed of polyimide (PI) or polycarbonate (PC). In addition to maintaining the substrate in a flat state, the back plate may, when the display device needs to be bent or folded, maintain a constant curvature of the display panel and suppress wrinkling that may occur on a surface of the display panel.

The substrate 110 according to an embodiment may be a glass substrate. For example, the substrate 110 formed of a glass material may be a thin glass substrate having a thickness equal to or smaller than about 100㎛, and may have a flexible characteristic. The material of the substrate 110 is also not limited thereto. The substrate 110 may further include a flexible polymer film made of other materials. For example, the flexible polymer film may be made of any one of polycarbonate (PC), acrylonitrile-butadiene-styrene copolymer (ABS), polymethyl methacrylate (PMMA), polyethylene naphthalate (PEN), polyethersulfone (PES), cyclic olefin copolymer (COC), a triacetyl cellulose (TAC) film, a polyvinyl alcohol (PVA) film, a polyimide (PI) film, and polystyrene (PS).

In addition, the substrate 110 may also comprise two or more layers that are bonded to each other or may be divided into two or more substrates.

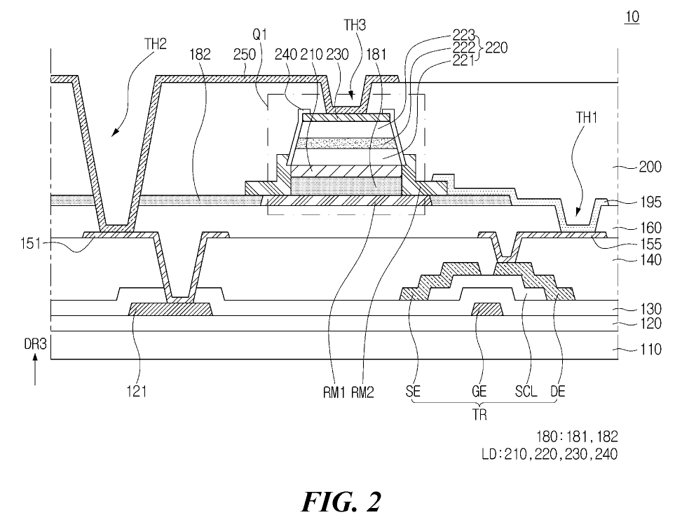

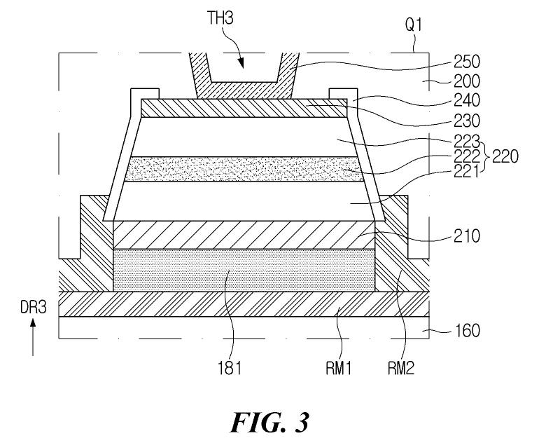

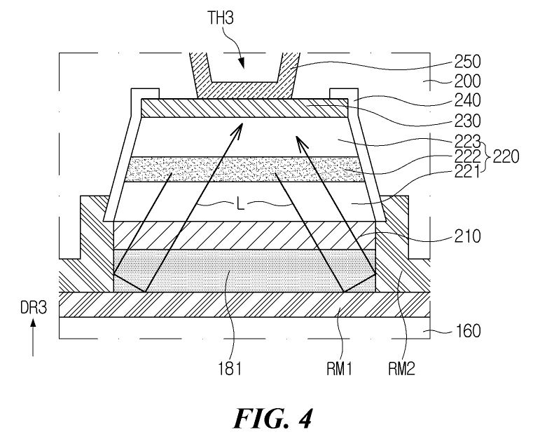

FIG. 2 is a view illustrating a cross-sectional structure of the sub-pixel according to an embodiment. FIG. 3 is an enlarged view of Q1 region of FIG. 2. FIG. 4 is a schematic view illustrating a path of light emitted from a light emitting layer.

Referring to FIGS. 2-4, the display device 10 may further include a transistor TR and a light emitting element LD disposed on the substrate 110. In addition, the display device 10 may further include lines electrically connect the transistor TR and the light emitting element LD to each other, and at least one insulating layer disposed between each component.

A buffer layer 120 may be disposed on the substrate 110. The buffer layer 120 may minimize or at least reduce spread of moisture or other foreign substances from the substrate 110. The buffer layer 120 may be formed of silicon oxide SiOx, silicon nitride SiNy, silicon oxynitride SiOxNy or the like. The buffer layer 120 may be formed as a single layer or a multi-layer of silicon oxide SiOx or silicon nitride , SiNy, silicon oxynitride SiOxNy or the like, but is not limited thereto.

The transistor TR may be disposed on the buffer layer 120. The transistor TR may be used as a driving element of the light emitting element LD. The transistor TR may be a driving transistor, but is not limited thereto.

The transistor TR may be, for example, a thin film transistor (TFT), an n-channel metal oxide semiconductor (NMOS), a p-channel metal oxide semiconductor (PMOS), a complementary metal oxide semiconductor (CMOS), a field effect transistor (FET), and the like, but is not limited thereto.

Hereinafter, it will be described in an assumption that the plurality of transistors TR are thin film transistors, but the disclosed technology is not limited thereto.

Each of the plurality of transistors TR may include a gate electrode GE, an active layer SCL, a source electrode SE, and a drain electrode DE.

The gate electrode GE and a common voltage line 121 may be disposed on the buffer layer 120. The gate electrode GE and the common voltage line 121 may be formed of a conductive material, for example, copper Cu, aluminum Al, molybdenum Mo, titanium Ti, or an alloy thereof, but are not limited thereto.

The common voltage line 121 may be electrically connected to the common power terminal (e.g., a high potential voltage terminal), receive a common power, and transfer the common power to a second electrode 230 of the light emitting element LD.

A gate insulating layer 130 may be disposed on the gate electrode GE. The gate insulating layer 130 may be a layer for insulating the gate electrode GE and the active layer SCL from each other, and may be formed of an insulating material. For example, the gate insulating layer 130 may be formed as a single layer or a multi-layer of silicon oxide SiOx, silicon nitride SiNy, silicon oxynitride SiOxNy or the like,, but is not limited thereto.

The active layer SCL may be disposed on the gate insulating layer 130. For example, the active layer SCL may be formed of an oxide semiconductor, an amorphous silicon or poly silicon, but is not limited thereto.

The source electrode SE and the drain electrode DE may be disposed to be spaced apart from each other on the active layer SCL. The source electrode SE and the drain electrode DE may be electrically connected to the active layer SCL. The source electrode SE and the drain electrode DE may be formed of a conductive material, for example, copper Cu, aluminum Al, molybdenum Mo, titanium Ti, or an alloy thereof, but are not limited thereto.

The first planarization layer 140 may be disposed on the transistor TR. The first planarization layer 140 may planarize an upper portion of the substrate 110 including the plurality of transistors TR.

In FIG. 2, the gate electrode GE may be illustrated as being disposed below the active layer SCL, but is not limited thereto. In other words, in FIG. 2, it is illustrated that the active layer SCL may be disposed between the source electrode SE and the drain electrode DE, and the gate electrode GE, but is not limited thereto.

For example, the gate electrode GE may be disposed on the active layer SCL. In this case, the gate electrode GE may be disposed between the source electrode SE and the drain electrode DE, and the active layer SCL.

The first planarization layer 140 may be formed as a single layer or a multi-layer, and may be formed of an organic material. For example, the first planarization layer 140 may be formed of an acryl-based organic material, but is not limited thereto. For another example, it may further be formed of a benzocyclobutene-based material. The first planarization layer 140 may include a contact hole configured to electrically connect the transistor TR and the second connection electrode 155 to each other.

Although not illustrated, a protection layer capable of protecting components below may be further disposed between the first planarization layer 140 and the transistor TR.

The first connection electrode 151 and the second connection electrode 155 may be disposed on the first planarization layer 140.

The first connection electrode 151 and the second connection electrode 155 may be disposed on the same layer, and may be formed of the same material. The first connection electrode 151 and the second connection electrode 155 may be disposed on the first planarization layer 140, and may be formed of a metal material. For example, the first connection electrode 151 and the second connection electrode 155 may include a light reflex conductive material, and may include at least one selected among aluminum Al, silver Ag, gold Au, platinum Pt, copper Cu, or the like.

The first connection electrode 151 may contact and may be electrically connected to the common voltage line 121 through a contact hole penetrating the first planarization layer 140 and the gate insulating layer 130 in a thickness direction (a third direction DR3).

The second connection electrode 155 may contact and electrically connected to the drain electrode DE of the transistor TR through the contact hole penetrating the first planarization layer 140 in the thickness direction (e.g., the third direction DR3).

A second planarization layer 160 may be disposed on the first connection electrode 151 and the second connection electrode 155. The second planarization layer 160 may be formed of an organic material. For example, the second planarization layer 160 may be formed of an acryl-based organic material, but is not limited thereto. The second planarization layer 160 may be formed of the same material as the first planarization layer 140, but is not limited thereto.

A first reflective electrode RM1 may be disposed on the second planarization layer 160. The first reflective electrode RM1 may reflect light emitted from the light emitting element LD to an upper side, and therefore, light-extraction efficiency of the light emitting element LD may be improved.

The first reflective electrode RM1 may be provided in plural, and may be disposed for each of the light emitting element LD. Each of the plurality of first reflective electrodes RM1 may be formed in an island shape, but may alternatively be formed in a mesh shape, a line shape, or a plate shape depending on the layout, and is not limited thereto.

A planar size (e.g., area) of the first reflective electrode RM1 may greater than the light emitting element LD. An entire region of the light emitting element LD may overlap the first reflective electrode RM1 in the thickness direction (e.g., the third direction DR3).

The first reflective electrode RM1 may include a material having a high reflectance. For example, the first reflective electrode RM1 may include one selected among aluminum Al, silver Ag, gold Au, platinum Pt, palladium Pd, titanium Ti, nickel Ni, chrome Cr, molybdenum Mo, tungsten W, or an alloy thereof. Other reflective conductive materials may also be used, but is not limited thereto.

An adhesive layer 180 may be disposed on the first reflective electrode RM1. The adhesive layer 180 may fix the light emitting element LD disposed on the adhesive layer 180. The adhesive layer 180 may be formed of an organic insulating layer. The adhesive layer 180 may be formed of a photocurable adhesive material which may be cured by light. For example, the adhesive layer 180 may be formed of an acryl-based material including a photosensitizer, but is not limited thereto. For another example, the adhesive layer may further be made of one of an epoxy resin, a UV-curable resin, a polyimide-based resin, a urethane-based resin, and polydimethylsiloxane (PDMS).

The adhesive layer 180 may include a first adhesive layer 181 and a second adhesive layer 182 separated from each other and spaced apart from each other. The first adhesive layer 181 and the second adhesive layer 182 may be formed of the same material by the same process.

The first adhesive layer 181 may be disposed on the first reflective electrode RM1. The first adhesive layer 181 may be disposed on an upper surface of the first reflective electrode RM1. Here, the upper surface of the first reflective electrode RM1 may refer to an opposite surface of a lower surface thereof opposed to the second planarization layer 160. The upper surface of the first reflective electrode RM1 may oppose the first electrode 210. The first adhesive layer 181 may be in direct contact with the upper surface of the first reflective electrode RM1.

A planar size (area) of the first adhesive layer 181 may be smaller than a planar size of the first reflective electrode RM1. An entire region of the first adhesive layer 181 may overlap the first reflective electrode RM1 in the thickness direction (the third direction DR3).

The first adhesive layer 181 may be separated from the second adhesive layer 182, and may be formed in an island shape in the whole pixel area. The first adhesive layer 181 may be provided in plural number, and may be disposed for each of the first reflective electrode RM1. The first adhesive layer 181 may be disposed for each of the light emitting element LD.

A side surface of the first adhesive layer 181 may be aligned with a side surface of the first electrode 210, but is not limited thereto.

As the second adhesive layer 182 is disposed on the side surface of first reflective electrode RM1, the second adhesive layer 182 may be disposed on the second planarization layer 160 which is not covered by the first reflective electrode RM1. The second adhesive layer 182 may be in direct contact with the side surface of the first reflective electrode RM1.

A height of an upper surface of the second adhesive layer 182 may be the same as a height of an upper surface of the first reflective electrode RM1, but is not limited thereto.

The first adhesive layer 181 and the second adhesive layer 182 may be spaced apart from each other, and the first reflective electrode RM1 may be exposed between the first adhesive layer 181 and the second adhesive layer 182.

The light emitting element LD may be disposed on the adhesive layer 180. The light emitting element LD may be disposed on the first adhesive layer 181. The light emitting element LD may be disposed on an upper surface of the first adhesive layer 181. The light emitting element LD may be in direct contact with the upper surface of the first adhesive layer 181.

The light emitting element LD may an LED (light emitting diode) or a micro-LED, but is not limited thereto. The light emitting element LD may have a vertical structure, but is not limited thereto.

The light emitting element LD may include a first electrode 210, a light emitting layer 220, the second electrode 230, and a passivation film 240. The light emitting layer 220 may include a first semiconductor layer 221, an active layer 222, and a second semiconductor layer 223. When the light emitting element LD has the vertical structure, the first electrode 210, the first semiconductor layer 221, the active layer 222, the second semiconductor layer 223, and the second electrode 230 may overlap in the thickness direction (the third direction DR3).

The first electrode 210, the light emitting layer 220 and the second electrode 230 may be disposed sequentially along the thickness direction (the third direction DR3). The first electrode 210, the light emitting layer 220 and the second electrode 230 may overlap in the thickness direction (e.g., the third direction DR3). The light emitting layer 220 may be disposed between the first electrode 210 and the second electrode 230.

The first electrode 210 may be disposed between the adhesive layer 180 and the light emitting layer 220. The first electrode 210 may be one among an anode electrode and a cathode electrode. For example, the first electrode 210 may be an anode electrode, but is not limited thereto.

When the first electrode 210 is an anode electrode, the first electrode 210 may be electrically connected to the transistor TR. When the first electrode 210 is an anode electrode, the transistor TR and the first semiconductor layer 221 may be electrically connected to each other through the first electrode 210.

The first electrode 210 may include a conductive material. The conductive material may be formed of a transparent conductive material such as, for example, ITO (Indium Tin Oxide) or IZO (Indium Zinc Oxide), or the like. Equivalent transparent conductive oxides may be substituted. However, the conductive material may be formed of at least one selected among opaque conductive materials such as nickel Ni, gold Au, platinum Pt, titanium Ti, aluminum Al, chrome Cr, copper Cu, silver Ag, or an alloy thereof, but is not limited thereto.

The light emitting layer 220 may be disposed on the first electrode 210. The first semiconductor layer 221, the active layer 222, and the second semiconductor layer 223 of the light emitting layer 220 may be sequentially disposed along the thickness direction. The active layer 222 may be disposed between the first semiconductor layer 221 and the second semiconductor layer 223.

The first semiconductor layer 221 may be disposed on the first electrode 210. The first semiconductor layer 221 may be disposed between the first electrode 210 and the active layer 222. The first semiconductor layer 221 may include a first type dopant. For example, the first semiconductor layer 221 may include a p-type dopant, but is not limited thereto.

When the first semiconductor layer 221 includes the p-type dopant, the first semiconductor layer 221, as a layer for supplying a hole to the active layer 222, may be formed by doping impurities such as magnesium (Mg), zinc (Zn), beryllium (Be), and the like to a material such as gallium nitride (GaN), indium aluminum phosphide (InAlP), gallium arsenide (GaAs), and the like.

The active layer 222 may be disposed on the first semiconductor layer 221. The active layer 222 may emit light by receiving a hole and an electron from the first semiconductor layer 221 and the second semiconductor layer 223. The active layer 222 may be formed in a single-layered or multi-layered multi-quantum well (MQW) structure, and may be formed of, for example, indium gallium nitride (InGaN) or gallium nitride (GaN), but is not limited thereto.

The second semiconductor layer 223 may be disposed on the active layer 222. The second semiconductor layer 223 may be disposed between the active layer 222 and the second electrode 230. The second semiconductor layer 223 may include a second type dopant which is different from the first type dopant. For example, the second semiconductor layer 223 may include an n-type dopant, but is not limited thereto.

When the second semiconductor layer 223 includes the n-type dopant, the second semiconductor layer 223, as a layer for supplying an electron to the active layer 222, may be formed by doping impurities such as silicon (Si), germanium (Ge), selenium (Se), tellurium (Te) and the like to a material such as gallium nitride (GaN), indium aluminum phosphide (InAlP), gallium arsenide (GaAs), and the like.

In the present disclosure, it is described that the first semiconductor layer 221 includes the p-type dopant and the second semiconductor layer 223 includes the n-type dopant, but are not limited thereto, and the first semiconductor layer 221 may include the n-type dopant and the second semiconductor layer 223 may include the p-type dopant.

The light emitting layer 220 may have a mesa structure. A side surface of the light emitting layer 220 may be formed as a slope inclined with respect to the thickness direction (e.g., the third direction DR3). A planar size of the light emitting layer 220 may decrease toward the second semiconductor layer 223 from the first semiconductor layer 221. A width of the light emitting layer 220 may decrease toward the second semiconductor layer 223 from the first semiconductor layer 221.

The second electrode 230 may be disposed on the second semiconductor layer 223. The second electrode 230 may be one among an anode electrode and a cathode electrode. For example, when the first electrode 210 is an anode electrode, the second electrode 230 may be a cathode electrode.

In the present disclosure, it is described that the first electrode 210 is an anode electrode, and the second electrode 230 is a cathode electrode, but are not limited thereto. For example, the first electrode 210 may be a cathode electrode, and the second electrode 230 may be an anode electrode.

When the second electrode 230 is a cathode electrode, the second electrode 230 may be electrically connected to the common voltage line 121. When the second electrode 230 is a cathode electrode, a common voltage terminal (e.g., a high-potential voltage terminal) and the second semiconductor layer 223 may be electrically connected to each other through the second electrode 230 and the common voltage line 121.

The second electrode 230 may include a conductive material. The conductive material may be formed of at least one selected among, for example, a transparent conductive material such as ITO (Indium Tin Oxide) or IZO (Indium Zinc Oxide), and an opaque conductive material such as nickel (Ni), gold (Au), platinum (Pt), titanium (Ti), aluminum (Al), chrome (Cr), copper (Cu), silver (Ag), or an alloy thereof, but is not limited thereto.

The passivation film 240 may be disposed on the side surface of the light emitting layer 220. The passivation film 240 may be disposed along a circumference of the light emitting layer 220 and may be disposed to surround the light emitting layer 220.

The passivation film 240 may be in direct contact with the side surface of the light emitting layer 220. The passivation film 240 may be disposed on side surfaces of the first semiconductor layer 221, the active layer 222, and the second semiconductor layer 223. The passivation film 240 may be in direct contact with the side surfaces of the first semiconductor layer 221, the active layer 222, and the second semiconductor layer 223.

The passivation film 240 may extend from the side surface of the light emitting layer 220, cover a side surface of the second electrode 230, and cover some of an upper surface of the second electrode 230. The passivation film 240 may expose at least some of the side surface of the first electrode 210.

The passivation film 240 may be formed of, for example, an inorganic insulating material such as silicon oxide, silicon nitride, silicon oxynitride, aluminum oxide, and the like, but is not limited thereto.

The passivation film 240 may protect the light emitting layer 220, and prevent a leakage current flowing in a side portion of the light emitting layer 220.

A second reflective electrode RM2 may be disposed on the first reflective electrode RM1. The second reflective electrode RM2 may be disposed on the first reflective electrode RM1 exposed between the first adhesive layer 181 and the second adhesive layer 182. The second reflective electrode RM2 may be disposed on an upper surface of the first reflective electrode RM1.

The second reflective electrode RM2 may be in direct contact with the first reflective electrode. The second reflective electrode RM2 may be in direct contact with the upper surface of the first reflective electrode RM1. The second reflective electrode RM2 may be in direct contact with the first reflective electrode RM1 exposed between the first adhesive layer 181 and the second adhesive layer 182.

The second reflective electrode RM2 may be disposed on a side surface of the first adhesive layer 181. The second reflective electrode RM2 may be in direct contact with the side surface of the first adhesive layer 181. The second reflective electrode RM2 may be disposed to surround the first adhesive layer 181.

The second reflective electrode RM2 may extend in the thickness direction (e.g., the third direction DR3) and may be disposed on a side surface of the first electrode 210. The second reflective electrode RM2 may be in direct contact with the side surface of the first electrode 210. The second reflective electrode RM2 may be disposed to surround the first electrode 210. Therefore, the second reflective electrode RM2 and the first electrode 210 may be smoothly be in contact with each other, and electrically connected to each other.

The second reflective electrode RM2 may further extend in the thickness direction (e.g., the third direction DR3) and may be disposed in some region of a side surface of the passivation film 240. The second reflective electrode RM2 may be in direct contact with some region of a side surface of the passivation film 240. The second reflective electrode RM2 may be disposed to surround some region of the side surface of the passivation film 240.

The second reflective electrode RM2 may be disposed across the first adhesive layer 181 and the second adhesive layer 182, but is not limited thereto. In an embodiment of the present disclosure, the second reflective electrode RM2 may be provided in various shapes. For example, the second reflective electrode RM2 may be provided to have a lower portion having a flat portion and a protruding portion protruding upward from one edge of the lower portion, thereby forming an “L”-like shape in a cross-section view. The flat lower portion may be in sufficient contact with the first reflective electrode RM1, thereby effectively blocking a path through which light leaks after being emitted from the LED.

The second reflective electrode RM2 may include a material having a high reflectance. The second reflective electrode RM2 may include the same material as that of the first reflective electrode RM1, but is not limited thereto.

As the second reflective electrode RM2 is disposed on the first reflective electrode RM1 and the second reflective electrode RM2 is in direct contact with the first reflective electrode RM1, light-extraction efficiency of light emitted from the light emitting element LD may be improved.

As illustrated in FIG. 4, as the reflective electrodes RM1 and RM2 are disposed around the light emitting element LD, light L emitted from the light emitting layer 220 and proceeding to a lower side may be reflected by at least one among the first reflective electrode RM1 and the second reflective electrode RM2 and proceed to an upper side. Here, the lower side may be a direction from the light emitting layer 220 to the first reflective electrode RM1, and the upper side may be a direction from the light emitting layer 220 to the second electrode 230.

As the first reflective electrode RM1 and the second reflective electrode RM2 are disposed to be in direct contact with each other, the light L emitted from the light emitting layer 220 and proceeding to the lower side may not get out through a portion between the first reflective electrode RM1 and the second reflective electrode RM2, may be reflected by at least one among the first reflective electrode RM1 and the second reflective electrode RM2, and proceed to the upper side. Herein, on the other hand, when the first adhesive layer 181 is formed inside a recessed structure formed by the first reflective electrode RM1 and the second reflective electrode RM2, a cavity is provided by the first adhesive layer 181, the first reflective electrode RM1, and the second reflective electrode RM2, wherein in the cavity light travels and is reflected, which further improves the efficiency of light reflection and travel.

For example, as the first reflective electrode RM1 and the second reflective electrode RM2 are disposed to be in direct contact with each other, it is possible to minimize or at least reduce leakage of the light L, emitted from the light emitting layer 220 and proceeding to the lower side, to the outside of the reflective electrodes RM1 and RM2, without being reflected and proceeding to the upper side. Further, the light-extraction efficiency of light emitted from the light emitting element LD may be improved, and low power of the display device 10 may be implemented, thereby power consumption can be reduced. Herein, various combined shapes may be formed between the first reflective electrode RM1 and the second reflective electrode RM2. For example, in a cross-sectional view, the first reflective electrode RM1 and the second reflective electrode RM2 may be combined to form a bowl-like shape, in which the first adhesive layer 181 may be filled, thereby forming a stable accommodating structure for connecting and positioning the LED element.

In addition, as the planar size of the first reflective electrode RM1 is greater than the light emitting element LD, the light emitting element LD and the second reflective electrode RM2 may be smoothly disposed on the first reflective electrode RM1 even though there may be an error by a process margin. Therefore, the second reflective electrode RM2 may be smoothly in contact with the first electrode 210 and the first reflective electrode RM1 even though there may be an error by a process margin. In other words, electrical connection of the light emitting element LD and lines (the reflective electrode, the connection electrode, and the like) in contact with the light emitting element LD may be smooth, and stability of a contact process may be improved.

A pixel connection electrode 195 may be disposed on the adhesive layer 180. The pixel connection electrode 195 may be formed of the same material as that of the common connection electrode 250, but is not limited thereto.

The pixel connection electrode 195 may include a transparent conductive material when the display device 10 is a top-emission type, and may include a light reflex conductive material when the display device 10 is a bottom-emission type. The transparent conductive material may be ITO (indium tin oxide) or IZO (indium zinc oxide), etc., but is not limited thereto. The light reflex conductive material may be Al, silver (Ag), Au, platinum (Pt), Cu, etc., but is not limited thereto. The pixel connection electrode 195, including a light reflex conductive material, may be a single layer including the light reflex conductive material, or may be a multi-layer formed by stacking the single layers.

The second planarization layer 160 may define a first through hole TH1 penetrating the second planarization layer 160 in the thickness direction (e.g., the third direction DR3) and exposing the second connection electrode 155.

The pixel connection electrode 195 may contact the second reflective electrode RM2, and be electrically connected to the first electrode 210. Through the first through hole TH1, the pixel connection electrode 195 may be in contact with the second connection electrode 155 exposed by the first through hole TH1 and electrically connected to the second connection electrode 155. In other words, the first electrode 210 and the second connection electrode 155 may be electrically connected to each other through the pixel connection electrode 195 and the second reflective electrode RM2.

The upper insulating layer 200 may be disposed on the pixel connection electrode 195. The upper insulating layer 200 may be disposed on the adhesive layer 180 while covering the light emitting element LD and the pixel connection electrode 195. The upper insulating layer 200 may have a thickness sufficient to cover a side surface and an upper surface of the light emitting element LD.

In the present disclosure, it is described that the upper insulating layer 200 is formed of a single layer, but is not limited thereto. For example, the upper insulating layer 200 may be formed of two or more layers.

The upper insulating layer 200 provides a planarized surface on the transistor TR and the light emitting element LD, and may fix a position of the light emitting element LD.

A common connection electrode 250 may be disposed on the upper insulating layer 200. The upper insulating layer 200, the adhesive layer 180 and the second planarization layer 160 may define a second through hole TH2 penetrating the upper insulating layer 200, the adhesive layer 180 and the second planarization layer 160 in the thickness direction (e.g., the third direction DR3) and exposing the first connection electrode 151.

In FIG. 2, an inner wall of the second through hole TH2 may be formed of a side surface of each of the upper insulating layer 200, the adhesive layer 180 and the second planarization layer 160, and the side surface of each of the upper insulating layer 200, the adhesive layer 180 and the second planarization layer 160 may be aligned.

However, the disclosed technology is not limited thereto, and the side surface of each of the upper insulating layer 200, the adhesive layer 180 and the second planarization layer 160 forming the inner wall of the second through hole TH2 may not be aligned. In other words, in the second through hole TH2, the upper insulating layer 200, the adhesive layer 180 and the second planarization layer 160 may have step differences.

Through the second through hole TH2, the common connection electrode 250 may be in contact with the first connection electrode 151 exposed by the second through hole TH2 and may be electrically connected to the first connection electrode 151.

The upper insulating layer 200 may define a third through hole TH3 penetrating the upper insulating layer 200 in the thickness direction (e.g., the third direction DR3) and exposing the light emitting element LD. The third through hole TH3 may expose the second electrode 230.

The common connection electrode 250 may be electrically connected to the second electrode 230 while being in contact with the second electrode 230.

The second electrode 230 and the first connection electrode 151 may be electrically connected to each other through the common connection electrode 250.

The common connection electrode 250 may include a transparent conductive material when the display device 10 is a top-emission type, and may include a light reflex conductive material when the display device 10 is a bottom-emission type. The transparent conductive material may be ITO (indium tin oxide) or IZO (indium zinc oxide), etc., but is not limited thereto. The light reflex conductive material may be Al, silver (Ag), Au, platinum (Pt), Cu, etc., but is not limited thereto. The common connection electrode 250, including the light reflex conductive material, may be a single layer including the light reflex conductive material, or may be a multi-layer formed by stacking the single layers.

Though not illustrated, after the common connection electrode 250 is patterned, a black matrix may be further disposed on the second through hole TH2, the upper insulating layer 200 and the common connection electrode 250. The black matrix may be disposed across an entire region of the display region DA (refer to FIG. 1) except a light emitting region of each pixel PX (refer to FIG. 1).

An upper protection layer, a cover glass, and the like capable of protecting components therebelow may be further disposed on the black matrix.

The light emitting element LD may be disposed in plural number in each of the sub-pixels SP1, SP2, and SP3 (refer to FIG. 1). For example, one or more light-emitting elements LD may be disposed in each of the sub-pixels SP1, SP2, and SP3 (refer to FIG. 1).

Therefore, when one or more of the plurality of light emitting elements LD disposed in each of the sub-pixels SP1, SP2, and SP3 (refer to FIG. 1) is defective, light may be emitted from the corresponding sub-pixels SP1, SP2, and SP3 through a remaining other light emitting element LD. Alternatively, all of the plurality of light-emitting elements LD disposed in the sub-pixels SP1, SP2, and SP3 (refer to FIG. 1) may operate as redundancy light-emitting elements LED which emit light.

Hereinafter, a method for manufacturing the display device 10 according to an embodiment will be described. While describing the method for manufacturing the display device 10 according to an embodiment, content which have been described with reference to FIGS. 1-4 will be briefly described, or description thereof will be omitted.

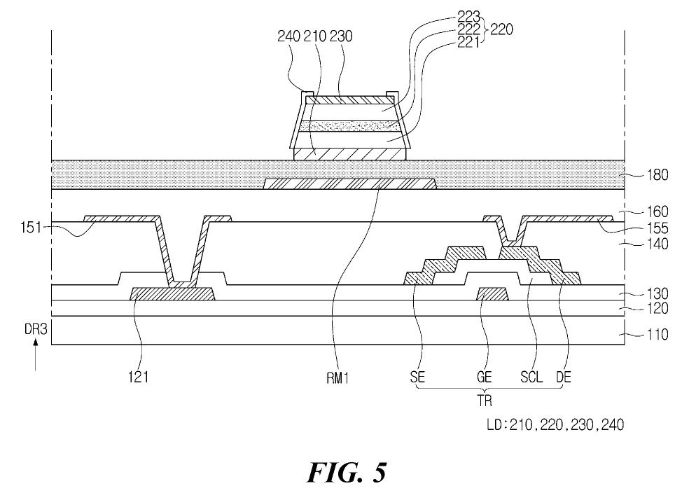

FIGS. 5-8 are views illustrating steps of manufacturing the display device according to an embodiment.

Referring to FIG. 5, the light emitting element LD may be transferred onto the substrate 110 on which the buffer layer 120, the transistor TR, the gate insulating layer 130, the first planarization layer 140, the second planarization layer 160, the adhesive layer 180, the connection electrodes 151 and 155, and the first reflective electrode RM1 are disposed. The light emitting element LD may be transferred onto the adhesive layer 180.

The first reflective electrode RM1 may be patterned and disposed on the second planarization layer 160.

The adhesive layer 180 may be disposed on an entire region of the second planarization layer 160 while covering the first reflective electrode RM1.

The light emitting element LD may be transferred onto the adhesive layer 180 in a region overlapping the first reflective electrode RM1 in the thickness direction (e.g., the third direction DR3).

After the light emitting element LD is transferred, a lighting test may be performed to determine whether the light emitting element LD is normal.

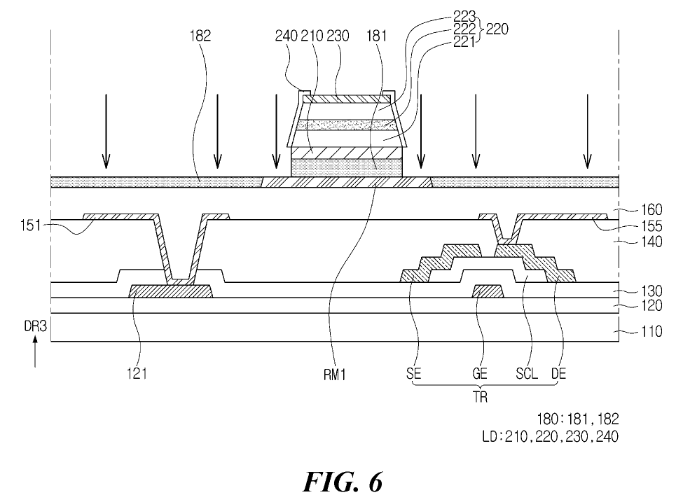

Next, referring to FIG. 6, by patterning the adhesive layer 180 disposed across the entire region of the second planarization layer 160, the first adhesive layer 181 and the second adhesive layer 182 separated from each other may be formed.

The light emitting element LD may serve as a mask when patterning the adhesive layer 180. Therefore, the adhesive layer 180 may not be removed and may remain in a region that the light emitting element LD and the adhesive layer 180 overlap each other in the thickness direction (e.g., the third direction DR3), and the first adhesive layer 181 may be formed.

After patterning the adhesive layer 180, an ashing and descum process may be further performed, but the disclosed technology is not limited thereto.

As the adhesive layer 180 is removed, some of the first reflective electrode RM1 may be exposed on an outside of the light emitting element LD.

The second adhesive layer 182 may be formed on the outside of the first reflective electrode RM1. Patterning of the adhesive layer 180 may be performed until some of the first reflective electrode RM1, which does not overlap the light emitting element LD, is exposed. Therefore, an upper surface of the second adhesive layer 182 and an upper surface of the first reflective electrode RM1 may have the same height.

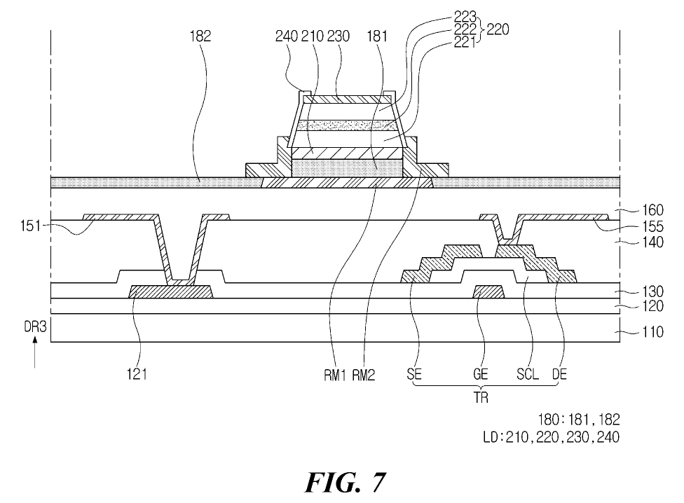

Next, referring to FIG. 7, the patterning is performed such that the second reflective electrode RM2 is disposed on the first reflective electrode RM1 exposed between the first adhesive layer 181 and the second adhesive layer 182. The second reflective electrode RM2 may be deposited to cover both the first reflective electrode RM1 and the second adhesive layer 182, and then patterned, but the disclosed technology is not limited thereto.

The patterned second reflective electrode RM2 may be disposed to surround the first adhesive layer 181, and be in contact with the first electrode 210. The second reflective electrode RM2 may be in contact with a side surface of the first electrode 210, but the disclosed technology is not limited thereto.

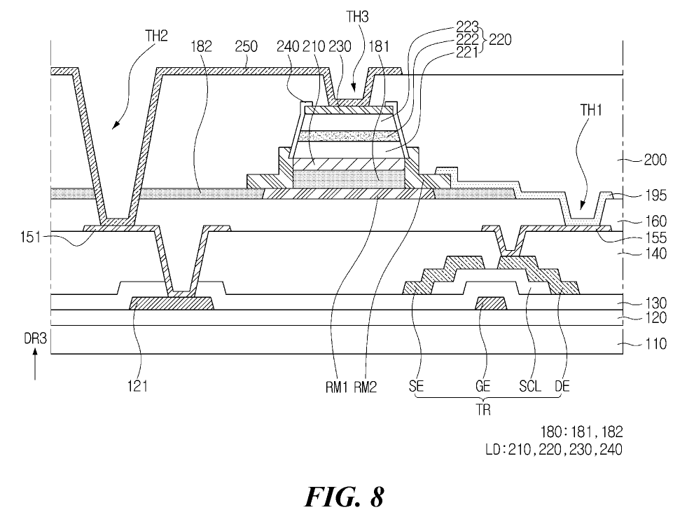

Next, referring to FIG. 8, the pixel connection electrode 195, the upper insulating layer 200, and the common connection electrode 250 may be sequentially formed.

First, by patterning the second planarization layer 160, the first through hole TH1 exposing the second connection electrode 155 may be formed.

Next, the pixel connection electrode 195 may be formed by patterning the pixel connection electrode 195 on the second planarization layer 160. One end of the pixel connection electrode 195 may be in contact with the second reflective electrode RM2, and another end thereof may be disposed inside the first through hole TH1 and may be in contact with the second connection electrode 155.

Next, the upper insulating layer 200 may be formed on the pixel connection electrode 195 and light emitting element LD. The upper insulating layer 200 may be disposed across the entire region of the second planarization layer 160 while covering the pixel connection electrode 195 and the light emitting element LD, but the disclosed technology is not limited thereto.

Next, the second through hole TH2 penetrating the upper insulating layer 200, the adhesive layer 180, and the second planarization layer 160 in the thickness direction (e.g., the third direction DR3) and exposing the first connection electrode 151, and the third through hole TH3 penetrating the upper insulating layer 200 in the thickness direction (e.g., the third direction DR3) and exposing the light emitting element LD may be formed.

Next, the common connection electrode 250 may be formed by patterning the common connection electrode 250 on the upper insulating layer 200. One end of the common connection electrode 250 may be disposed inside the second through hole TH2 and be in contact with the first connection electrode 151 and another end thereof may be disposed inside the third through hole TH3 and be in contact with the second electrode 230.

As such, as the step of transferring the light emitting element LD and the step of forming the conductive layer (the pixel connection electrode 195 and the like) are separately performed, stability of each process may be improved, and stability of the contact process by which the light emitting element LD and the conductive layer (the pixel connection electrode 195 and the like) are in contact with each other may be improved. Therefore, the process efficiency may be improved and the process expenses may be reduced, and further, the production energy may be reduced.

Hereinafter, other embodiments of the present disclosure will be described. Among components included in other embodiments, the content substantially the same as the content which have been described with reference to FIGS. 1-8 will be granted with the same reference numeral and the redundant content there among may be briefly described, or may be omitted.

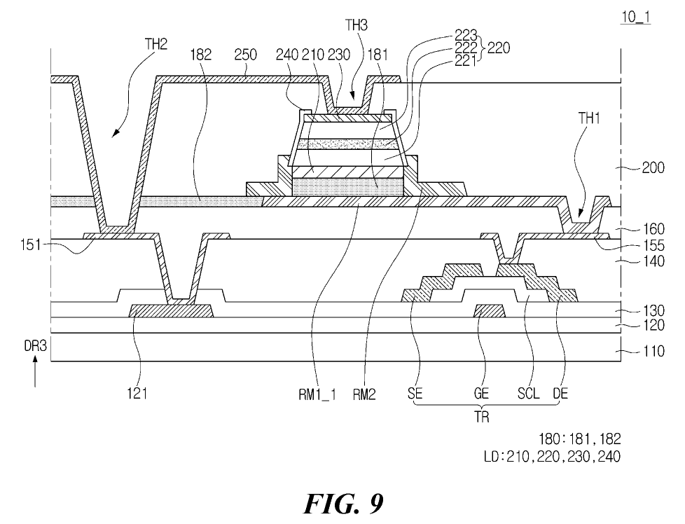

FIG. 9 is a cross-sectional view of a display device according to another embodiment.

Referring to FIG. 9, in the display device 10_1 according to the present embodiment, the pixel connection electrode 195 (refer to FIG. 2) may be omitted.

The display device 10_1 may include a first reflective electrode RM1_1. The first reflective electrode RM1_1 may be disposed for each of the light emitting element LD.

One end of the first reflective electrode RM1_1 may be disposed below the light emitting element LD and be in contact with the second reflective electrode RM2 and another end thereof may be disposed inside the first through hole TH1 defined by the second planarization layer 160, and be in contact with the second connection electrode 155. The second reflective electrode RM2 may be in contact with the first electrode 210.

Therefore, through the first reflective electrode RM1_1 and the second reflective electrode RM2, the first electrode 210 and the second connection electrode 155 may be electrically connected to each other.

In this case as well, as the first reflective electrode RM1_1 and the second reflective electrode RM2 are in direct contact with each other, it is possible to reflect the light emitted from the light emitting element LD more smoothly toward the upper side, and further, the light-extraction efficiency of the light emitting element LD may be improved. Further, the first reflective electrode RM1_1 may extend from below the light emitting element LD toward one side to reach an upper position overlapping with the transistor TFT, and may be connected to the transistor TR through a contact hole TH1. This saves an additional process for forming a pixel electrode, and at the same time enhances an effect of reflecting light toward the outside.

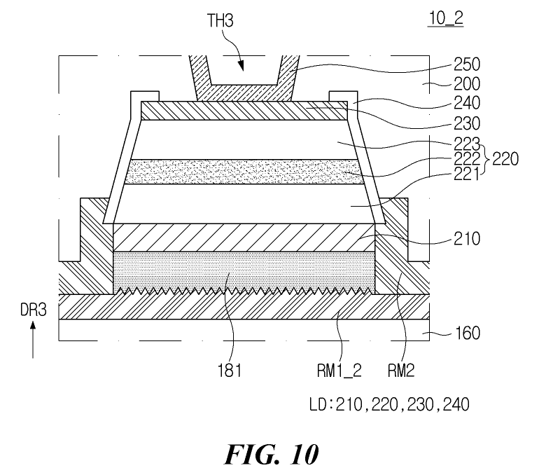

FIG. 10 is a cross-sectional view of a display device according to still another embodiment. FIG. 10 is an enlarged view which enlarged a periphery of the light emitting element LD.

Referring to FIG. 10, a display device 10_2 according to the present embodiment may include a first reflective electrode RM1_2, and a surface of at least some of the first reflective electrode RM1_2 may be formed in a concave-convex structure, or may have a rough surface pattern, a dimple pattern, or a texturing structure to scatter light.

Some of an upper surface of the first reflective electrode RM1_2 may be formed in the concave-convex structure. The upper surface of the first reflective electrode RM1_2 may refer to a surface opposed to the first adhesive layer 181. A region of the upper surface of the first reflective electrode RM1_2 which overlaps the first adhesive layer 181 in the thickness direction (e.g., the third direction DR3) may be formed of the concave-convex structure.

In this case as well, as the first reflective electrode RM1_2 and the second reflective electrode RM2 are in direct contact with each other, it is possible to reflect the light emitted from the light emitting element LD more smoothly toward the upper side, and further, the light-extraction efficiency of the light emitting element LD may be improved.

Further, as the upper surface of the first reflective electrode RM1_2 is formed of the concave-convex structure, it is possible to reflect the light emitted from the light emitting element LD more smoothly toward the upper side, and further, the light-extraction efficiency of the light emitting element LD may be improved.

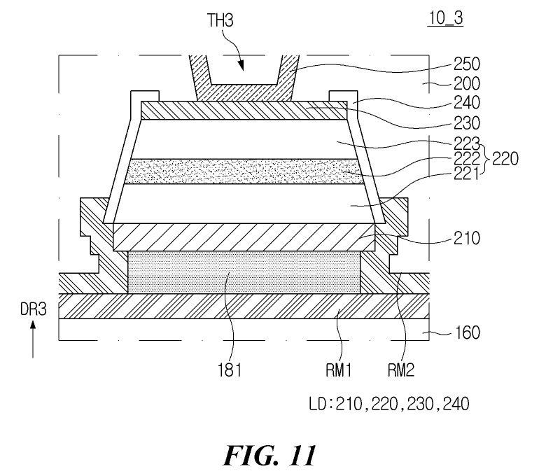

FIG. 11 is a cross-sectional view of a display device according to still another embodiment. FIG. 11 is an enlarged view which enlarged a periphery of the light emitting element LD.

Referring to FIG. 11, in the display device 10_3 according to the present embodiment, the first adhesive layer 181 may expose some of a lower surface of the first electrode 210. Here, the lower surface of the first electrode 210 may refer to a surface opposed to the first adhesive layer 181. The second reflective electrode RM2 may be in contact with a side surface and the lower surface of the first electrode 210.

Some of the lower surface of the first electrode 210 exposed by the first adhesive layer 181 may be disposed around an edge of the lower surface of the first electrode 210. A side surface of the first electrode 210 may protrude more outward than a side surface of the first adhesive layer 181.

As illustrated in FIG. 6, in the process of patterning the adhesive layer 180, the patterning process may be performed as an isotropic etching process. At this instance, the side surface of the first adhesive layer 181 may be etched, and may be positioned on an inner side than the side surface of the first electrode 210.

Thereafter, the second reflective electrode RM2 may be formed. The second reflective electrode RM2 may have a high step coverage, and the second reflective electrode RM2 may be disposed on not only a side surface of the first electrode 210, but also, the lower surface of the first electrode 210 exposed by the first adhesive layer 181. The second reflective electrode RM2 may be in direct contact with a side surface and a lower surface of the first electrode 210. Further, in this case, the second reflective electrode RM2 further contacts a side surface of the first adhesive layer 181, a portion of a lower surface of the first electrode 210, a side surface of the first electrode 210, and a portion of the passivation layer 240. The second reflective electrode RM2 may further cover a step at a boundary between different portions to form a bent shape. In this case, a combination of the first reflective electrode RM1 and the second reflective electrode RM2 may further improve light reflection efficiency.

In this case as well, as the first reflective electrode RM1 and the second reflective electrode RM2 are in direct contact with each other, it is possible to reflect the light emitted from the light emitting element LD more smoothly toward the upper side, and further, the light-extraction efficiency of the light emitting element LD may be improved.

Further, as the second reflective electrode RM2 is in contact with a side surface and the lower surface of the first electrode 210, a contact area increases, and a contact between the second reflective electrode RM2 and the first electrode 210 may be performed more stably.

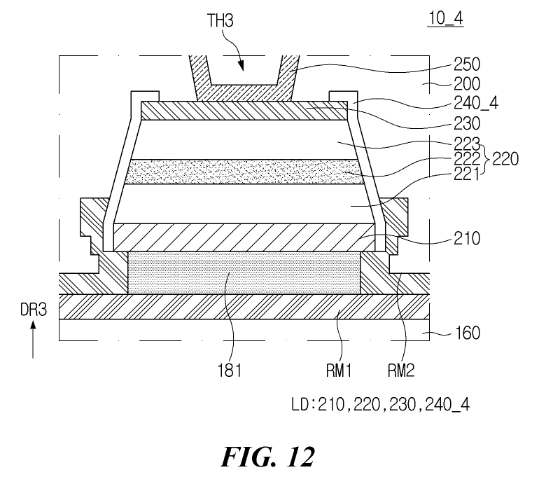

FIG. 12 is a cross-sectional view of a display device according to still another embodiment. FIG. 12 is an enlarged view which enlarged a periphery of the light emitting element LD.

Referring to FIG. 12, the display device 10_4 according to the present embodiment may include a passivation film 240_4, and the present embodiment is different from the embodiment in FIG. 11 that the passivation film 240_4 covers up to the side surface of the first electrode 210.

The passivation film 240_4 extends further while covering the second electrode 230 and the light emitting layer 220, and may cover up to the side surface of the first electrode 210. The passivation film 240_4 may cover an entire region of the side surface of the first electrode 210, but is not limited thereto. The passivation film 240_4 may be in direct contact with the side surface of the first electrode 210. In this case, the second reflective electrode RM2 may be electrically connected to the first electrode 210 only by contacting a portion of a lower surface of the first electrode 210.

The passivation film 240_4 may be disposed between the second reflective electrode RM2 and the first electrode 210.

The second reflective electrode RM2 and the first electrode 210 may be in contact with each other through the lower surface of the first electrode 210 exposed by the first adhesive layer 181, and may be electrically connected to each other.

In this case as well, as the first reflective electrode RM1 and the second reflective electrode RM2 are in direct contact with each other, it is possible to reflect the light emitted from the light emitting element LD more smoothly toward the upper side, and further, the light-extraction efficiency of the light emitting element LD may be improved.

Further, as the passivation film 240_4 covers all of a side surface of each of the first electrode 210, the light emitting layer 220, and the second electrode 230, a leakage current may be prevented more smoothly and an unnecessary short circuit with the conductive layers therearound may be suppressed or prevented.

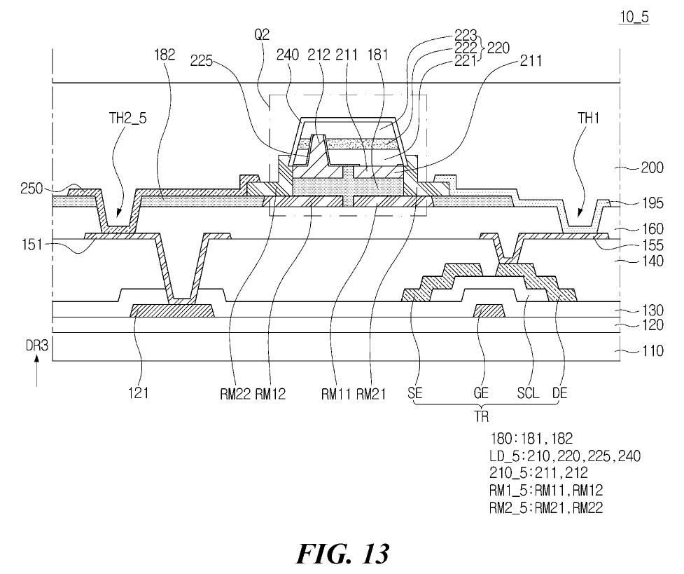

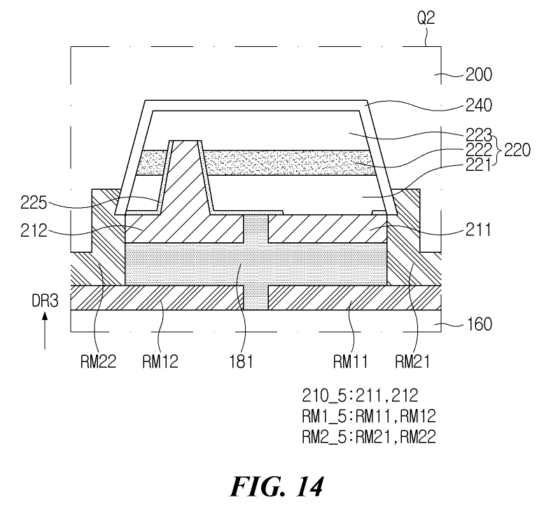

FIG. 13 is a cross-sectional view of a display device according to still another embodiment. FIG. 14 is an enlarged view of Q2 region of FIG. 13.

Referring to FIGS. 13 and 14, a display device 10_5 according to the present embodiment may include a light emitting element LD_5, and the light emitting element LD_5 may have a flip-type structure. The light emitting element LD_5 may be formed of a flip-chip.

A first reflective electrode RM1_5 may include an eleventh reflective electrode RM11 and a twelfth reflective electrode RM12 separated from each other. The eleventh reflective electrode RM11 and the twelfth reflective electrode RM12 may be insulated from each other.

A second reflective electrode RM2_5 may include a twenty-first reflective electrode RM21 and a twenty-second reflective electrode RM22 separated from each other. The twenty-first reflective electrode RM21 and the twenty-second reflective electrode RM22 may be insulated from each other. In other words, in an embodiment of the present disclosure, the first reflective electrode RM1_5 may include two sub-portions that are independent of and insulated from each other, and the second reflective electrode RM2_5 may also include two sub-portions that are independent of and insulated from each other. Such an electrode structure can help a flip chip form an effective electrical connection.

The twenty-first reflective electrode RM21 may be disposed on the eleventh reflective electrode RM11 and may be in direct contact with the eleventh reflective electrode RM11. The twenty-second reflective electrode RM22 may be disposed on the twelfth reflective electrode RM12, and may be in direct contact with the twelfth reflective electrode RM12.

The light emitting element LD_5 may include a first electrode 210_5, the light emitting layer 220, a semiconductor insulating layer 225, and the passivation film 240.

The first electrode 210_5 may include an eleventh electrode 211 and a twelfth electrode 212 separated from each other. The eleventh electrode 211 and the twelfth electrode 212 may be insulated from each other.

The eleventh electrode 211 and the twelfth electrode 212 may be disposed on the same layer. The eleventh electrode 211 and the twelfth electrode 212 may be disposed on the first adhesive layer 181.

The eleventh electrode 211 and the twenty-first reflective electrode RM21 may be in contact with each other and electrically connected to each other, and the twelfth electrode 212 and the twenty-second reflective electrode RM22 may be in contact with each other and electrically connected to each other.

The eleventh electrode 211 and the first semiconductor layer 221 may be in contact with each other and electrically connected to each other. The twelfth electrode 212 and the second semiconductor layer 223 may be in contact with each other and electrically connected to each other. The eleventh electrode 211 may be an anode electrode and the twelfth electrode 212 may be a cathode electrode, but the disclosed technology is not limited thereto.

Therefore, the second electrode 230 in FIG. 2 in the light emitting element LD_5 may be omitted, and a role of the second electrode 230 in FIG. 2 may be performed by the twelfth electrode 212.

The light emitting layer 220 may be disposed on the eleventh electrode 211 and the twelfth electrode 212. The twelfth electrode 212 may include a protrusion protruding toward the second semiconductor layer 223. In more detail, the twelfth electrode 212 may include the protrusion disposed between the light emitting layer 220 and the first adhesive layer 181, and protruding toward the second semiconductor layer 223. With this configuration, the twelfth electrode 212 may be in contact with the second semiconductor layer 223, and electrically connected to the second semiconductor layer 223.

The semiconductor insulating layer 225 may be disposed between the twelfth electrode 212 and the first semiconductor layer 221 and between the twelfth electrode 212 and the active layer 222. The semiconductor insulating layer 225 may include an inorganic insulating material, but is not limited thereto.

Through the semiconductor insulating layer 225, a short circuit between the twelfth electrode 212 and the first semiconductor layer 221 and a short circuit between the twelfth electrode 212 and the active layer 222 may be prevented.

The pixel connection electrode 195 may be in contact with and electrically connected to the twenty-first reflective electrode RM21, and the common connection electrode 250 may be in contact with and electrically connected to the twenty-second reflective electrode RM22.

The common connection electrode 250 may be in contact with the first connection electrode 151 through the second through hole TH2_5 defined by the second planarization layer 160 and the second adhesive layer 182.

The common connection electrode 250 may be disposed on the same layer as the pixel connection electrode 195, but the disclosed technology is not limited thereto.

The upper insulating layer 200 may be disposed on the pixel connection electrode 195, the common connection electrode 250 and the light emitting element LD_5.

In this case as well, as the first reflective electrode RM1_5 and the second reflective electrode RM2_5 are in direct contact with each other, it is possible to reflect the light emitted from the light emitting element LD_5 more smoothly toward the upper side, and further, the light-extraction efficiency of the light emitting element LD_5 may be improved.

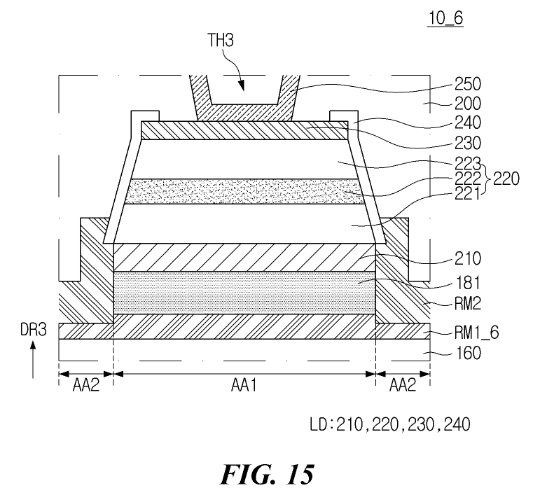

FIG. 15 is a cross-sectional view of a display device according to still another embodiment. FIG. 15 is an enlarged view which enlarged a periphery of the light emitting element LD.

Referring to FIG. 15, a display device 10_6 according to the present embodiment may include a first reflective electrode RM1_6 having thicknesses different from each other per region.

The first reflective electrode RM1_6 having thicknesses different from each other may include a first region AA1 and a second region AA2. A thickness of the first region AA1 may be thicker than that of the second region AA2. Here, a thickness of the first region AA1 and a thickness of the second region AA2 may refer to a width in the thickness direction (e.g., the third direction DR3).

The first region AA1 may overlap the first adhesive layer 181 in the thickness direction (e.g., the third direction DR3). The second region AA2 may not overlap the first adhesive layer 181 in the thickness direction (e.g., the third direction DR3).

The second region AA2 may be disposed around the first region AA1. The second region AA2 may be disposed to surround the first region AA1, but the disclosed technology is not limited thereto.

Herein turning back and making reference to FIG. 6, in the process of patterning the adhesive layer 180 to expose the first reflective electrode RM1_6, some region of the first reflective electrode RM1_6 which does not overlap the adhesive layer 180 may be further etched in the thickness direction, and may be formed to have a thinner thickness than the remaining other regions which overlap the adhesive layer 180.

In this case as well, as the first reflective electrode RM1_6 and the second reflective electrode RM2 are in direct contact with each other, it is possible to reflect the light emitted from the light emitting element LD more smoothly toward the upper side, and further, the light-extraction efficiency of the light emitting element LD may be improved.

The display device according to various embodiments of the present disclosure may be described as below.

One embodiment is a display device, including: a substrate; a transistor disposed on the substrate; a planarization layer disposed on the transistor; a first reflective electrode disposed on the planarization layer; a first adhesive layer disposed on the first reflective electrode; a light emitting element disposed on the first adhesive layer; and a second reflective electrode in contact with the light emitting element, and the first reflective electrode and the second reflective electrode may be in direct contact with each other.

According to various embodiments of the present disclosure, the light emitting element may be disposed on an upper surface of the first adhesive layer, and the second reflective electrode may be disposed on a side surface of the first adhesive layer.

According to various embodiments of the present disclosure, the light emitting element may be in direct contact with the upper surface of the first adhesive layer, and the second reflective electrode may be in direct contact with the side surface of the first adhesive layer.

According to various embodiments of the present disclosure, the second reflective electrode may surround the first adhesive layer.

According to various embodiments of the present disclosure, the second reflective electrode may be disposed on an upper surface of the first reflective electrode.

According to various embodiments of the present disclosure, the display device may further include: a second adhesive layer separated from the first adhesive layer and disposed on a side surface of the first reflective electrode, and the second reflective electrode may be in direct contact with the first reflective electrode exposed between the first adhesive layer and the second adhesive layer.

According to various embodiments of the present disclosure, a height of an upper surface of the second adhesive layer may be identical to a height of an upper surface of the first reflective electrode.

According to various embodiments of the present disclosure, the first adhesive layer and the second adhesive layer may include the same material.

According to various embodiments of the present disclosure, the light emitting element may include a first electrode, a light emitting layer and a second electrode stacked sequentially, and the second reflective electrode may be in contact with the first electrode.

According to various embodiments of the present disclosure, the second reflective electrode may be in direct contact with a side surface of the first electrode.

According to various embodiments of the present disclosure, the first reflective electrode has a first thickness in a first region and has a second thickness in a second region, and the thickness of the first electrode in the first region is greater than the thickness in the second region to form a step region, and the second reflective electrode is disposed in the step region to contact a side surface of the first electrode.

According to various embodiments of the present disclosure, the first reflective electrode includes a first sub-reflective electrode and a second sub-reflective electrode insulated from each other, and the second reflective electrode includes a first sub-reflective electrode and a second sub-reflective electrode insulated from each other, and a sub-reflective electrode of the first reflective electrode and a sub-reflective electrode of the second reflective electrode are in electrical contact with each other.

According to various embodiments of the present disclosure, the first adhesive layer may expose some of a lower surface of the first electrode, and the second reflective electrode may be in direct contact with the lower surface of the first electrode exposed by the first adhesive layer.

According to various embodiments of the present disclosure, the display device may further include: a pixel connection electrode disposed on the planarization layer, and the pixel connection electrode may have one end in contact with the second reflective electrode and another end electrically connected to the transistor.

According to various embodiments of the present disclosure, the first reflective electrode may have one end in contact with the second reflective electrode and another end disposed inside a through hole defined by the planarization layer and electrically connected to the transistor.

According to various embodiments of the present disclosure, a planar size of the first adhesive layer may be smaller than a planar size of the first reflective electrode, and an entire region of the first adhesive layer may overlap the first reflective electrode in a thickness direction.

According to various embodiments of the present disclosure, a planar size of the light emitting element may be smaller than a planar size of the first reflective electrode, and an entire region of the light emitting element may overlap the first reflective electrode in the thickness direction.

According to various embodiments of the present disclosure, in a region overlapping the first adhesive layer, an upper surface of the first reflective electrode may have a concave-convex pattern.

Another embodiment is a display device, including: a substrate; a transistor disposed on the substrate; a planarization layer disposed on the transistor; a first reflective electrode disposed on the planarization layer; a first adhesive layer disposed on an upper surface of the first reflective electrode; a light emitting element disposed on the first adhesive layer; and a second reflective electrode disposed on the upper surface of the first reflective electrode, and the second reflective electrode may be disposed to surround the first adhesive layer.

According to various embodiments of the present disclosure, the second reflective electrode may be in contact with the light emitting element and in direct contact with the first reflective electrode.

According to various embodiments of the present disclosure, the second reflective electrode may be in direct contact with a side surface of the first adhesive layer.

According to various embodiments of the present disclosure, the light emitting element may be in direct contact with an upper surface of the first adhesive layer.

According to various embodiments of the present disclosure, a display device, comprising: a substrate; at least one transistor and a light emitting element disposed on the substrate; a planarization layer disposed on the transistor; a light emitting element accommodating member positioned on the planarization layer; and wherein the light emitting element accommodating member surrounds a bottom surface and at least a portion of a side surface of the light emitting element to accommodate the light emitting element, and the light emitting element accommodating member has reflective characteristics.

According to various embodiments of the present disclosure, wherein the light emitting element accommodating member forms a bowl-shaped structure to accommodate the light emitting element.

According to various embodiments of the present disclosure, wherein the accommodating member includes a reflective metal portion disposed to surround a bottom surface and at least a portion of a side surface of the light emitting element, and an adhesive portion disposed within the reflective metal portion.

According to various embodiments of the present disclosure, wherein the reflective metal portion includes a first reflective metal portion disposed below a bottom surface of the light emitting element, and a second reflective metal portion disposed to surround at least a portion of a side surface of the light emitting element, and the adhesive portion is located between the first reflective metal portion and the bottom surface of the light emitting element, and the second reflective metal portion contacts at least one electrode of the light emitting element.

According to various embodiments of the present disclosure, wherein a portion of the first reflective metal portion and a portion of the second reflective metal portion are in direct contact with each other in a region outside a region where the light emitting element is disposed, to sufficiently reflect light emitted from the light emitting element.

The embodiments of the present disclosure have been described with reference to accompanying drawings. Those of ordinary skill in the art will recognize that the present disclosure may be embodied in other specific forms without departing from its spirit or essential characteristics. The described embodiments are to be considered in all respects only as illustrative and not restrictive. The scope of the present disclosure is therefore indicated by the appended claims rather than by the foregoing description. All changes which come within meaning and range of equivalency of the claims are to be embraced within the scope of the present disclosure.

### REFERENCE NUMERALS

10: display device

110: substrate

TR: transistor

180: adhesive layer

181: first adhesive layer

182: second adhesive layer

LD: light emitting element

210: first electrode

220: light emitting layer

230: second electrode

240: passivation film

200: upper insulating layer

RM1: first reflective electrode

RM2: second reflective electrode

TH: through hole

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display device, comprising:
a substrate;
a transistor disposed on the substrate;
a planarization layer disposed on the transistor;
a first reflective electrode disposed on the planarization layer;
a first adhesive layer disposed on the first reflective electrode;
a light emitting element disposed on the first adhesive layer; and
a second reflective electrode in contact with the light emitting element,
wherein the first reflective electrode and the second reflective electrode are in direct contact with each other.

2. The display device of claim 1,
wherein the light emitting element is disposed on an upper surface of the first adhesive layer, and
wherein the second reflective electrode is disposed on a side surface of the first adhesive layer.

3. The display device of claim 2,
wherein the light emitting element is in direct contact with the upper surface of the first adhesive layer, and
wherein the second reflective electrode is in direct contact with the side surface of the first adhesive layer.

4. The display device of claim 3, wherein the second reflective electrode surrounds the first adhesive layer.

5. The display device of claim 1, wherein the second reflective electrode is disposed on an upper surface of the first reflective electrode.

6. The display device of claim 5, further comprising:
a second adhesive layer separated from the first adhesive layer and disposed on a side surface of the first reflective electrode,
wherein the second reflective electrode is in direct contact with the first reflective electrode exposed between the first adhesive layer and the second adhesive layer.

7. The display device of claim 6, wherein a height of an upper surface of the second adhesive layer is identical to a height of an upper surface of the first reflective electrode.

8. The display device of claim 7, wherein the first adhesive layer and the second adhesive layer comprise a same material.

9. The display device of claim 1,
wherein the light emitting element comprises a first electrode, a light emitting layer and a second electrode stacked sequentially, and
wherein the second reflective electrode is in contact with the first electrode.

10. The display device of claim 9, wherein the second reflective electrode is in direct contact with a side surface of the first electrode.

11. The display device of claim 9, wherein the first reflective electrode has a first thickness in a first region and has a second thickness in a second region, and the thickness of the first reflective electrode in the first region is greater than the thickness of the first reflective electrode in the second region to form a step region, and the second reflective electrode is disposed in the step region to contact a side surface of the first electrode.

12. The display device of claim 9, wherein the first reflective electrode includes a first sub-reflective electrode and a second sub-reflective electrode insulated from each other, and the second reflective electrode includes a first sub-reflective electrode and a second sub-reflective electrode insulated from each other, and a sub-reflective electrode of the first reflective electrode and a sub-reflective electrode of the second reflective electrode are in electrical contact with each other.

13. The display device of claim 9,
wherein the first adhesive layer exposes some of a lower surface of the first electrode, and
wherein the second reflective electrode is in direct contact with the lower surface of the first electrode exposed by the first adhesive layer.

14. The display device of claim 9, further comprising:
a pixel connection electrode disposed on the planarization layer,
wherein the pixel connection electrode has one end in contact with the second reflective electrode and another end electrically connected to the transistor.

15. The display device of claim 9, wherein the first reflective electrode has one end in contact with the second reflective electrode and another end disposed inside a through hole defined by the planarization layer and electrically connected to the transistor.

16. The display device of claim 1,
wherein a planar size of the first adhesive layer is smaller than a planar size of the first reflective electrode, and
wherein an entire region of the first adhesive layer overlaps the first reflective electrode in a thickness direction.

17. The display device of claim 16,
wherein a planar size of the light emitting element is smaller than a planar size of the first reflective electrode, and
wherein an entire region of the light emitting element overlaps the first reflective electrode in the thickness direction.

18. The display device of claim 1, wherein in a region overlapping the first adhesive layer, an upper surface of the first reflective electrode has a concave-convex pattern.

19. A display device, comprising:
a substrate;
a transistor disposed on the substrate;
a planarization layer disposed on the transistor;
a first reflective electrode disposed on the planarization layer;
a first adhesive layer disposed on an upper surface of the first reflective electrode;
a light emitting element disposed on the first adhesive layer; and
a second reflective electrode disposed on the upper surface of the first reflective electrode,
wherein the second reflective electrode is disposed to surround at least a portion of a side surface of the light emitting element.

20. The display device of claim 19, wherein the second reflective electrode is in contact with the light emitting element and in direct contact with the first reflective electrode.

21. The display device of claim 19, wherein the second reflective electrode is in direct contact with a side surface of the first adhesive layer.

22. The display device of claim 21, wherein the light emitting element is in direct contact with an upper surface of the first adhesive layer.

23. A display device, comprising:
a substrate;
at least one transistor and a light emitting element disposed on the substrate;
a planarization layer disposed on the at least one transistor; and
a light emitting element accommodating member positioned on the planarization layer,
wherein the light emitting element accommodating member surrounds a bottom surface and at least a portion of a side surface of the light emitting element to accommodate the light emitting element, and the light emitting element accommodating member has reflective characteristics.

24. The display device of claim 23, wherein the light emitting element accommodating member forms a bowl-shaped structure to accommodate the light emitting element.

25. The display device of claim 23, wherein the light emitting element accommodating member includes a reflective metal portion disposed to surround a bottom surface and at least a portion of a side surface of the light emitting element, and an adhesive portion disposed within the reflective metal portion.

26. The display device of claim 25,
wherein the reflective metal portion includes a first reflective metal portion disposed below a bottom surface of the light emitting element, and a second reflective metal portion disposed to surround at least a portion of a side surface of the light emitting element, and the adhesive portion is located between the first reflective metal portion and the bottom surface of the light emitting element, and
wherein the second reflective metal portion contacts at least one electrode of the light emitting element.

27. The display device of claim 26, wherein a portion of the first reflective metal portion and a portion of the second reflective metal portion are in direct contact with each other in a region outside a region where the light emitting element is disposed, to reflect light emitted from the light emitting element.
